(19) United States
(12) Patent Application Publication
(10) Pub. No.: US 2023/0420321 A1
(43) Pub. Date: Dec. 28, 2023

(54) SEMICONDUCTOR DEVICE

(71) Applicant: ROHM CO., LTD., Kyoto-shi (JP)

(72) Inventor: Takumi KANDA, Kyoto-shi (JP)

(21) Appl. No.: 18/464,509

(22) Filed: Sep. 11, 2023

Related U.S. Application Data
(63) Continuation of application No. PCT/JP2022/016446, filed on Mar. 31, 2022.

(30) Foreign Application Priority Data
Apr. 27, 2021 (JP) 2021-074911

(51) Int. Cl. H01L 23/31; H01L 23/00; H01L 23/495; H01L 25/07

(52) U.S. Cl. CPC H01L 23/3121; H01L 2224/73265; H01L 24/32; H01L 24/73; H01L 24/40; H01L 23/49513; H01L 23/49568; H01L 23/49562; H01L 25/072; H01L 2924/13091; H01L 2224/48245; H01L 2224/32245; H01L 2224/4001; H01L 2224/32013; H01L 2224/40245; H01L 2224/73221; H01L 2224/73213; H01L 2224/73215; H01L 2224/73263; H01L 24/48

(57) ABSTRACT

A semiconductor device includes: first and second die pads spaced from each other in a first direction; a semiconductor element mounted on at least one of the first and the second die pads; and a sealing resin. The sealing resin is longer in the first direction than in a second direction. The first die pad has a first end surface, a second end surface, and a first corner end surface. The first corner end surface is a flat surface that is covered with the sealing resin, and that is inclined relative to the first end surface and the second end surface. The first corner end surface has a first inclination angle relative to the first end surface and a second inclination angle relative to the second end surface. Either the first inclination angle or the second inclination angle is in the range of 60° to 85° both inclusive.

### TECHNICAL FIELD

The present disclosure relates to a semiconductor device.

### BACKGROUND ART

JP-A-2018-14490 discloses an example of a semiconductor device including a die pad, a semiconductor element mounted on the die pad, and a sealing resin covering the semiconductor element. The semiconductor element is a switching element such as a MOSFET. The semiconductor device can be used to configure a power conversion circuit.

The semiconductor device disclosed in JP-A-2018-14490 constitutes either an upper arm circuit or a lower arm circuit in the power conversion circuit. On the other hand, when a single semiconductor device is configured to include an upper arm circuit and a lower arm circuit, it is necessary to provide two die pads so that semiconductor elements can be mounted on the respective die pads. In this case, more heat will be transferred from the semiconductor elements to the sealing resin via the two die pads. As a result, the sealing resin is more likely to suffer from large thermal stress concentration, which may lead to a crack in the sealing resin.

### BRIEF DESCRIPTION OF THE DRAWINGS

FIG. 1 is a perspective view illustrating a semiconductor device according to a first embodiment of the present disclosure.

FIG. 2 is a plan view illustrating the semiconductor device of FIG. 1.

FIG. 3 is a plan view corresponding to FIG. 2, with a sealing resin shown transparent.

FIG. 4 is a bottom view illustrating the semiconductor device of FIG. 1.

FIG. 5 is a front view illustrating the semiconductor device of FIG. 1.

FIG. 6 is a right-side view illustrating the semiconductor device of FIG. 1.

FIG. 7 is a right-side view corresponding to FIG. 6, with a sealing resin shown transparent.

FIG. 8 is a cross-sectional view taken along line VIII-VIII in FIG. 3.

FIG. 9 is a cross-sectional view taken along line IX-IX in FIG. 3.

FIG. 10 is a partially enlarged view of FIG. 8.

FIG. 11 is a partially enlarged view of FIG. 8.

FIG. 12 is a partially enlarged view of FIG. 8.

FIG. 13 is a partially enlarged view of FIG. 9.

FIG. 14 is a partially enlarged view of FIG. 3.

FIG. 15 is a partially enlarged view of FIG. 3.

FIG. 16 is a partially enlarged view of FIG. 3.

FIG. 17 is a partially enlarged view of FIG. 3.

FIG. 18 is a partially enlarged plan view illustrating a variation of the semiconductor device of FIG. 1, with a sealing resin shown transparent.

FIG. 19 is a partially enlarged right-side view illustrating the semiconductor device of FIG. 18, with the sealing resin shown transparent.

FIG. 20 is a plan view illustrating a semiconductor device according to a second embodiment of the present disclosure, with a sealing resin shown transparent.

FIG. 21 is a partially enlarged cross-sectional view taken along line XXI-XXI in FIG. 20.

FIG. 22 is a partially enlarged cross-sectional view taken along line XXII-XXII in FIG. 20.

### DETAILED DESCRIPTION OF EMBODIMENTS

Embodiments of the present disclosure will be described with reference to the accompanying drawings.

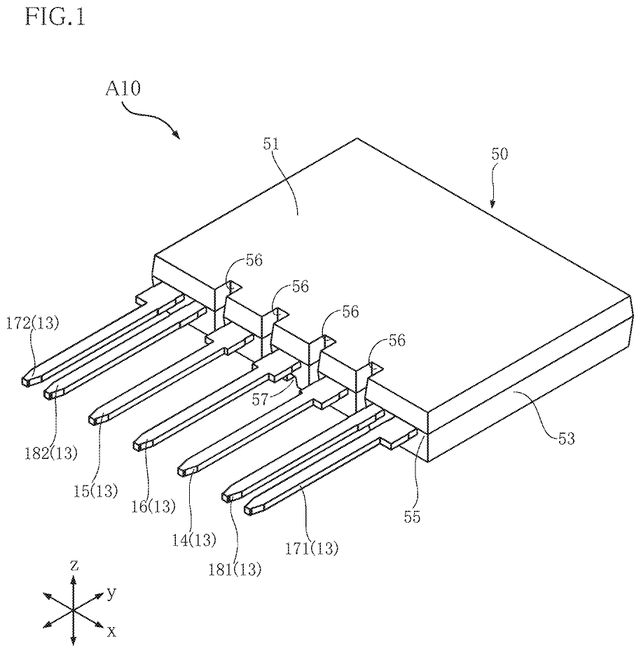

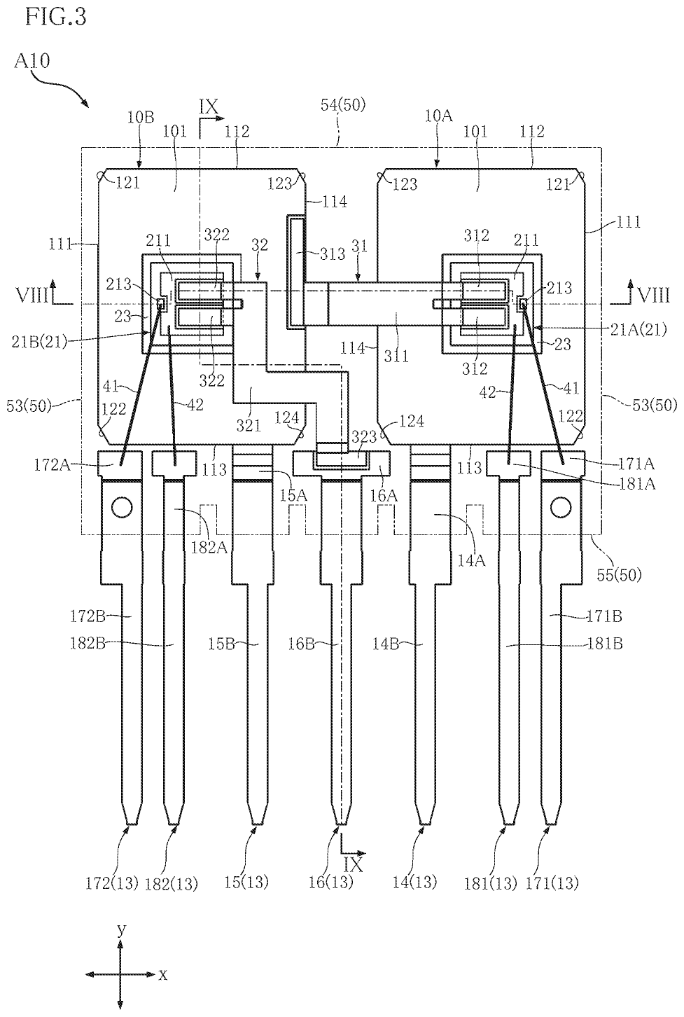

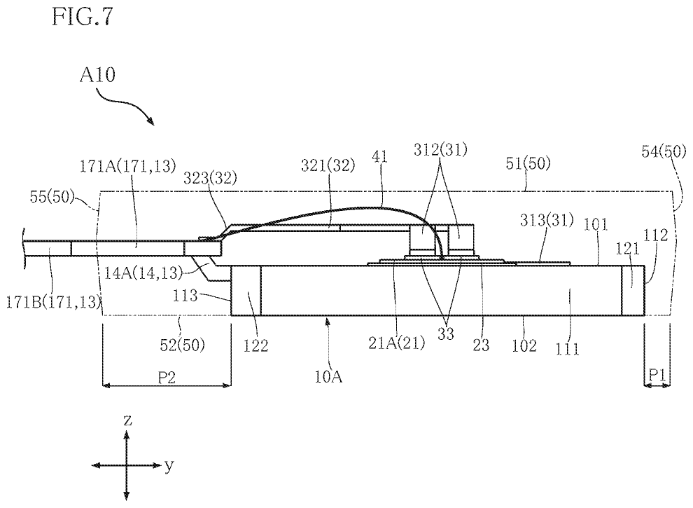

The following describes a semiconductor device A10 according to a first embodiment of the present disclosure, with reference to FIGS. 1 to 17. The semiconductor device A10 includes a first die pad 10A, a second die pad 10B, a plurality of terminal leads 13, a semiconductor element 21, a first conductive member 31, a second conductive member 32, a pair of gate wires 41, a pair of detection wires 42, and a sealing resin 50. In FIGS. 3 and 7, the sealing resin 50 is shown transparent for convenience of understanding and indicated by an imaginary line (two-dot chain line). In FIG. 3, line VIII-VIII and line IX-IX are each indicated by a single-dot chain line.

In the description of the semiconductor device A10, the thickness direction of the first die pad 10A (or the second die pad 10B) is referred to as “thickness direction z” for convenience. A direction perpendicular to the thickness direction z is referred to as “first direction x”. The direction perpendicular to both of the thickness direction z and the first direction x is referred to as “second direction y”.

The semiconductor device A10 uses the semiconductor element 21 to convert the DC source voltage applied to a first input terminal 14 and a second input terminal 16 of the terminal leads 13 into AC power. The AC power obtained by the conversion is inputted from an output terminal 15 of the terminal leads 13 to a power-supply target such as a motor. The semiconductor device A10 is used in a power conversion circuit such as an inverter.

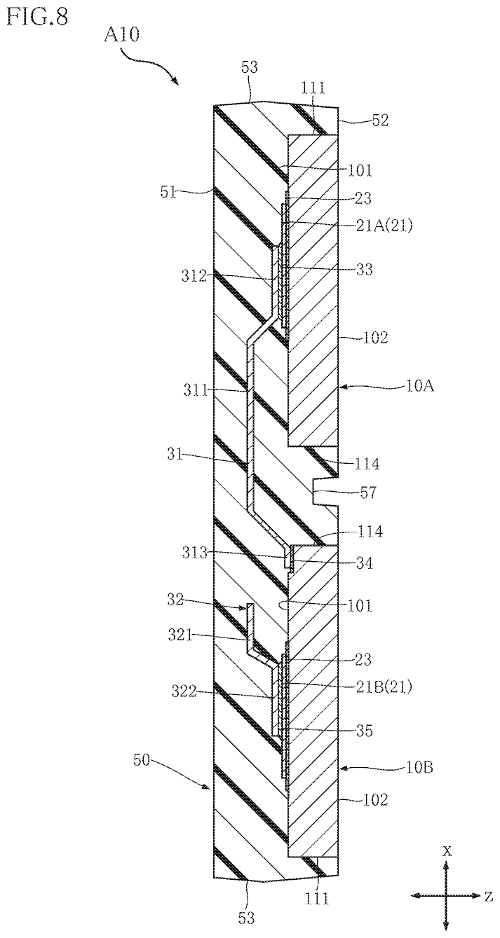

As shown in FIGS. 3 and 8, the first die pad 10A and the second die pad 10B are spaced apart from each other in the first direction x. The first die pad 10A is formed from the same lead frame from which the second die pad 10B and the terminal leads 13 are formed. The lead frame is made of copper (Cu) or a copper alloy. Accordingly, each of the first die pad 10A, the second die pad 10B, and the terminal leads 13 contains copper (i.e., each member contains copper) in its composition. Each of the first die pad 10A and the second die pad 10B has an obverse surface 101 and a reverse surface 102. The obverse surface 101 faces in the thickness direction z. The obverse surface 101 is covered with the sealing resin 50. The semiconductor element 21 is mounted on the obverse surface 101. Accordingly, the reverse surface 102 faces away from where the semiconductor element 21 is located in the thickness direction z. The reverse surface 102 is exposed from the sealing resin 50. The reverse surface 102 is plated with tin (Sn), for example.

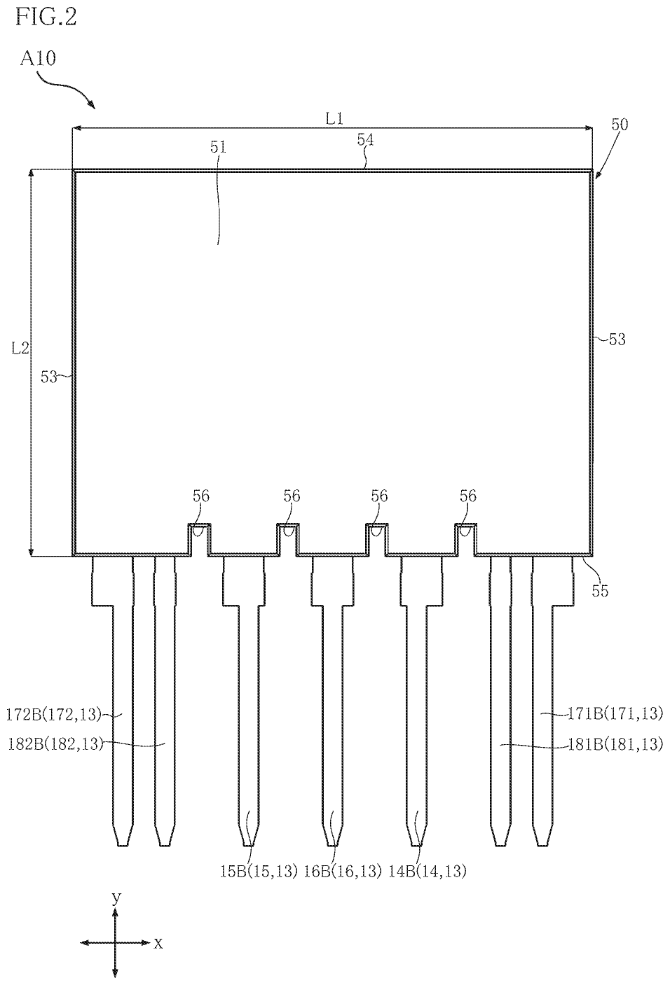

As shown in FIG. 3 and FIGS. 7 to 9, the sealing resin 50 covers the semiconductor element 21, the first conductive member 31, the second conductive member 32, and at least a portion of each of the first die pad 10A and the second die pad 10B. The sealing resin 50 further covers a portion of each of the terminal leads 13. The sealing resin 50 is electrically insulative. The sealing resin 50 is made of a material containing a black epoxy resin, for example. As shown in FIG. 2, the dimension L1 of the sealing resin 50 in the first direction x is longer than the dimension L2 of the sealing resin 50 in the second direction y. The sealing resin 50 has a top surface 51, a bottom surface 52, a pair of first side surfaces 53, a second side surface 54, a third side surface 55, a plurality of recesses 56, and a groove 57.

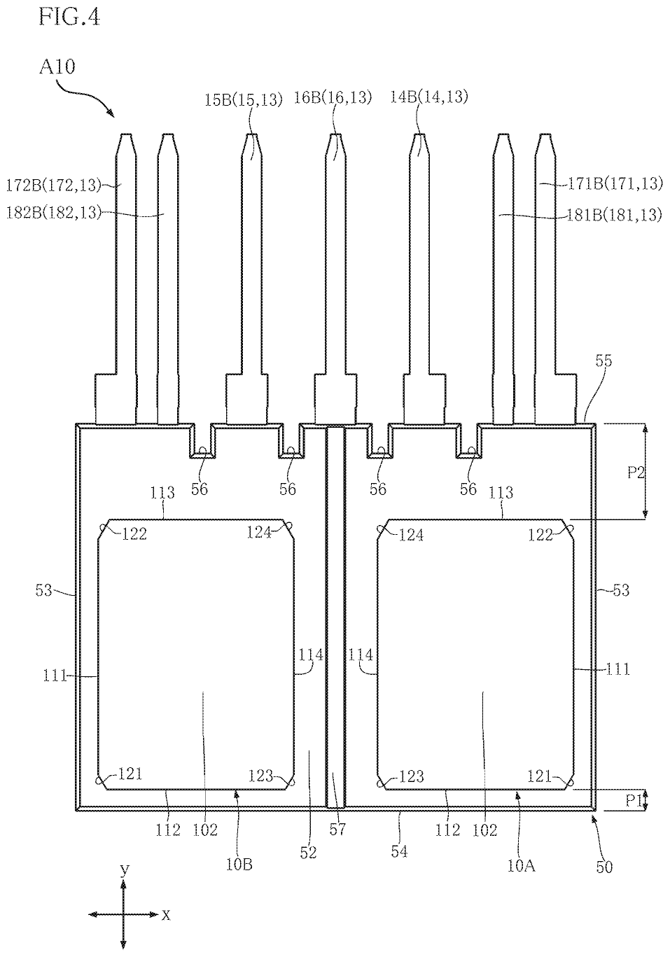

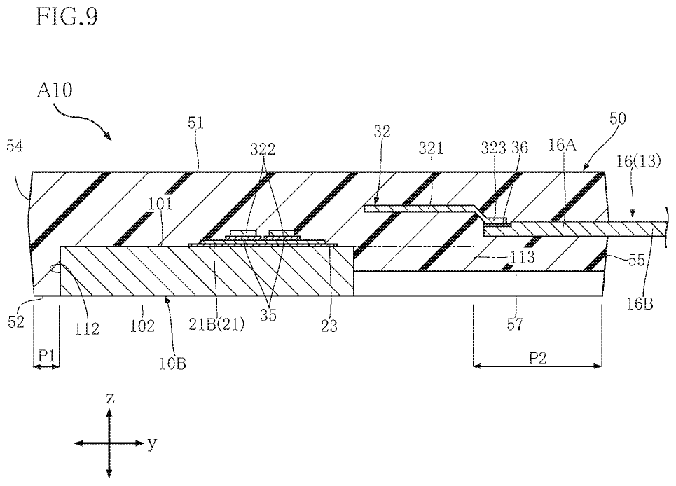

As shown in FIG. 8, the top surface 51 faces the same side as the obverse surfaces 101 of the first die pad 10A and the second die pad 10B in the thickness direction z. As shown in FIGS. 8 and 9, the bottom surface 52 faces away from the top surface 51 in the thickness direction z. As shown in FIG. 4, the reverse surface 102 of the first die pad 10A and the reverse surface 102 of the second die pad 10B are exposed from the bottom surface 52.

As shown in FIGS. 2, 4 and 5, the pair of first side surfaces 53 are spaced apart from each other in the first direction x. The pair of first side surfaces 53 face in the first direction x and extend in the second direction y. The pair of first side surfaces 53 are connected to the top surface 51 and the bottom surface 52.

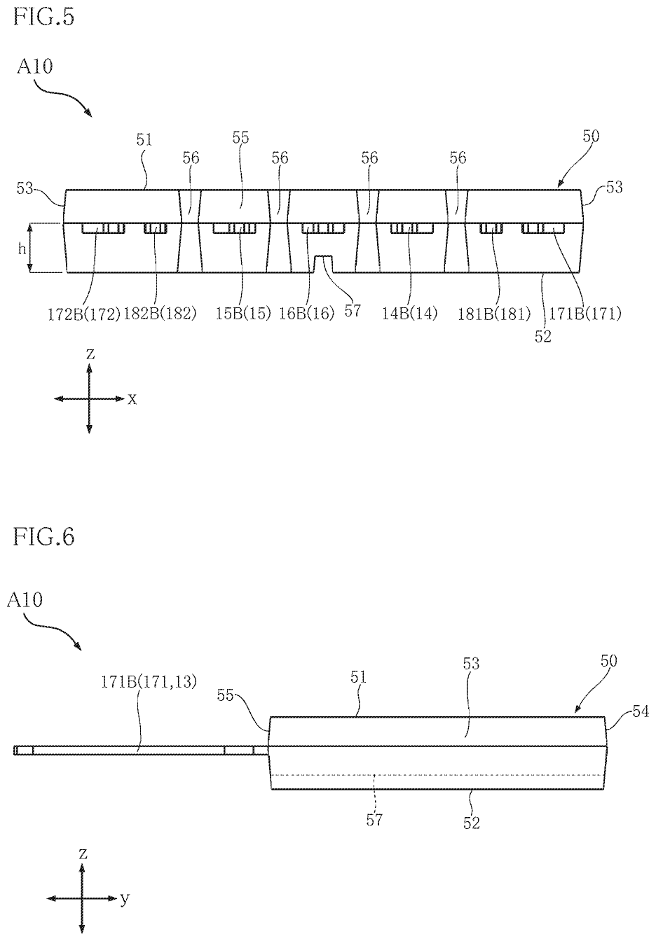

As shown in FIGS. 2, 4 and 6, the second side surface 54 and the third side surface 55 are spaced apart from each other in the second direction y. The second side surface 54 and the third side surface 55 face away from each other in the second direction y, and extend in the first direction x. The second side surface 54 and the third side surface 55 are connected to the top surface 51 and the bottom surface 52. As shown in FIG. 5, the terminal leads 13 are exposed from the third side surface 55.

As shown in FIGS. 2, 4 and 5, the recesses 56 are recessed from the third side surface 55 in the second direction y, and extend from the top surface 51 to the bottom surface 52 in the thickness direction z. In the first direction x, the recesses 56 are positioned one each between the first input terminal 14 and a first detection terminal 181, between the first input terminal 14 and the second input terminal 16, between the output terminal 15 and the second input terminal 16, and between the output terminal 15 and a second detection terminal 182.

As shown in FIGS. 4, 5, 8 and 9, the groove 57 is recessed from the bottom surface 52 in the thickness direction z, and extends in the second direction y (i.e., is elongated in the second direction y). Two sides of the groove 57 in the second direction y are connected to the second side surface 54 and the third side surface 55, respectively. As viewed in the thickness direction z, the groove 57 separates the reverse surface 102 of the first die pad 10A and the reverse surface 102 of the second die pad 10B from each other.

As shown in FIGS. 3 and 4, each of the first die pad 10A and the second die pad 10B has a first end surface 111, a second end surface 112, a third end surface 113, and a fourth end surface 114. The first end surface 111, the second end surface 112, the third end surface 113, and the fourth end surface 114 are covered with the sealing resin 50. The first end surface 111 faces in the first direction x and extends in the second direction y. The first end surface 111 is located closest to one of the pair of first side surfaces 53 of the sealing resin 50. The second end surface 112 faces in the second direction y and extends in the first direction x. The second end surface 112 is located closest to the second side surface 54 of the sealing resin 50. The third end surface 113 faces away from the second end surface 112 in the second direction y, and extends in the first direction x. The third end surface 113 is located closest to the third side surface 55 of the sealing resin 50. The fourth end surface 114 faces away from the first end surface 111 in the first direction x, and extends in the second direction y. As shown in FIG. 8, the groove 57 is located between the fourth end surface 114 of the first die pad 10A and the fourth end surface 114 of the second die pad 10B.

As shown in FIGS. 4 and 7, the distance P2 between the third end surface 113 and the third side surface 55 is longer than the distance P1 between the second end surface 112 and the second side surface 54.

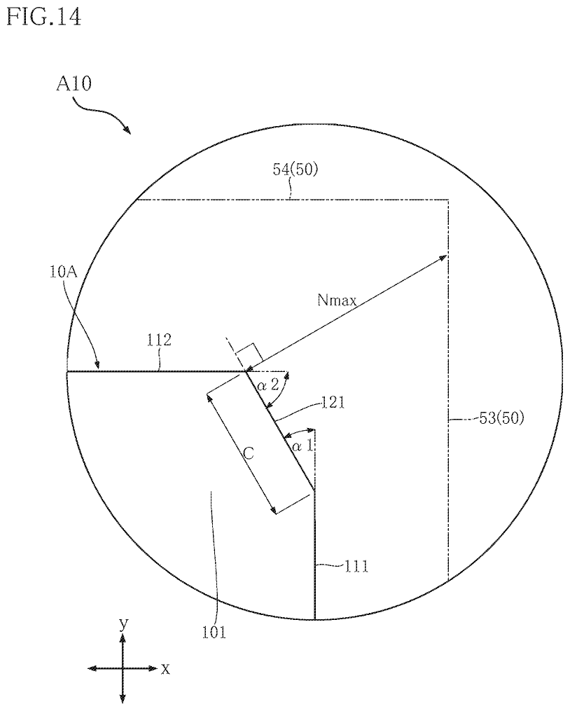

As shown in FIGS. 3, 4 and 7, each of the first die pad 10A and the second die pad 10B has a first corner end surface 121. The first corner end surface 121 is located between the first end surface 111 and the second end surface 112 and at a corner of either the first die pad 10A or the second die pad 10B. The first corner end surface 121 is a flat surface that is covered with the sealing resin 50, and that is inclined relative to the first end surface 111 and the second end surface 112. As shown in FIG. 14, the first corner end surface 121 has a first inclination angle α1 relative to the first end surface 111 and a second inclination angle α2 relative to the second end surface 112. Either the first inclination angle α1 or the second inclination angle α2 is in the range of 600 to 85° (both inclusive).

Furthermore, as shown in FIG. 14, the longest normal Nₘₐₓ is set for the first corner end surface 121. The longest normal Nₘₐₓ represents the maximum value of the normal of the first corner end surface 121 of either the first die pad 10A or the second die pad 10B, where the normal extends from the first corner end surface 121 to one of the pair of first side surfaces 53 of the sealing resin 50 that is closer to the first corner end surface 121. The longest normal Nₘₐₓ is 1.0 to 1.5 times greater than the length of the line of intersection C (see FIG. 14) between the first corner end surface 121 and the virtual plane having the first direction x and the second direction y as in-plane directions.

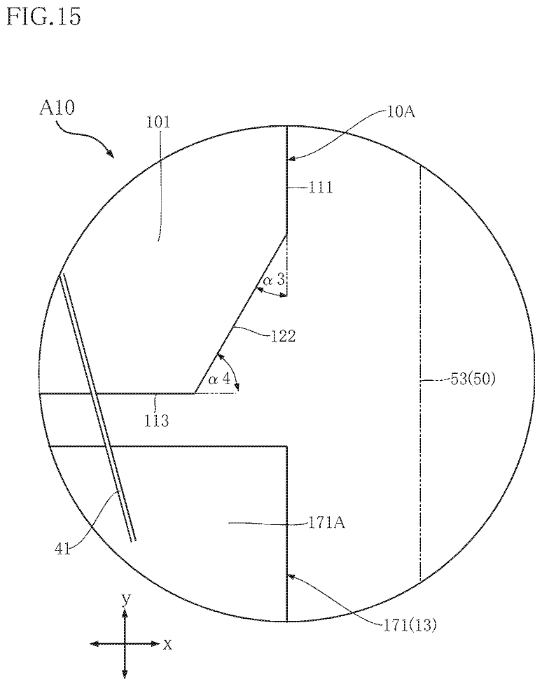

As shown in FIGS. 3, 4 and 7, each of the first die pad 10A and the second die pad 10B has a second corner end surface 122. The second corner end surface 122 is located between the first end surface 111 and the third end surface 113 and at a corner of one of the first die pad 10A and the second die pad 10B. The second corner end surface 122 is a flat surface that is covered with the sealing resin 50, and that is inclined relative to the first end surface 111 and the third end surface 113. As shown in FIG. 15, the second corner end surface 122 has a third inclination angle α3 relative to the first end surface 111 and a fourth inclination angle α4 relative to the third end surface 113. Either the third inclination angle α3 or the fourth inclination angle α4 is in the range of 60° to 85° (both inclusive).

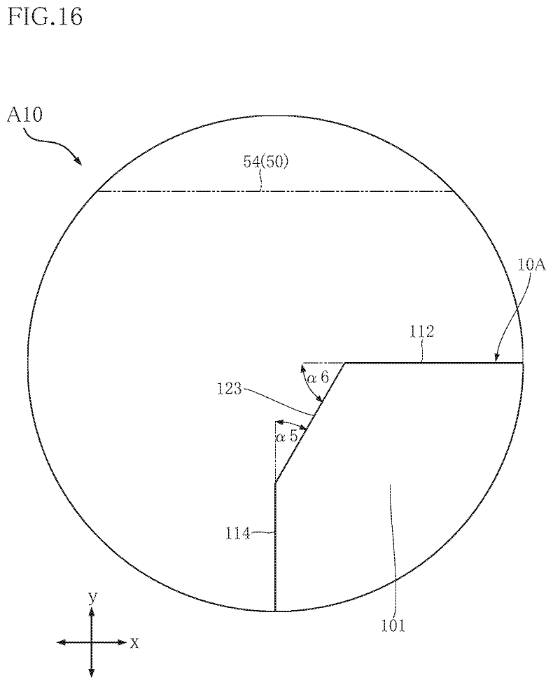

As shown in FIGS. 3 and 4, each of the first die pad 10A and the second die pad 10B has a third corner end surface 123. The third corner end surface 123 is located between the second end surface 112 and the fourth end surface 114 and at a corner of one of the first die pad 10A and the second die pad 10B. The third corner end surface 123 is a flat surface that is covered with the sealing resin 50, and that is inclined relative to the second end surface 112 and the fourth end surface 114. As shown in FIG. 16, the third corner end surface 123 has a fifth inclination angle α5 relative to the fourth end surface 114 and a sixth inclination angle α6 relative to the second end surface 112. Either the fifth inclination angle α5 or the sixth inclination angle α6 is in the range of 600 to 85° (both inclusive).

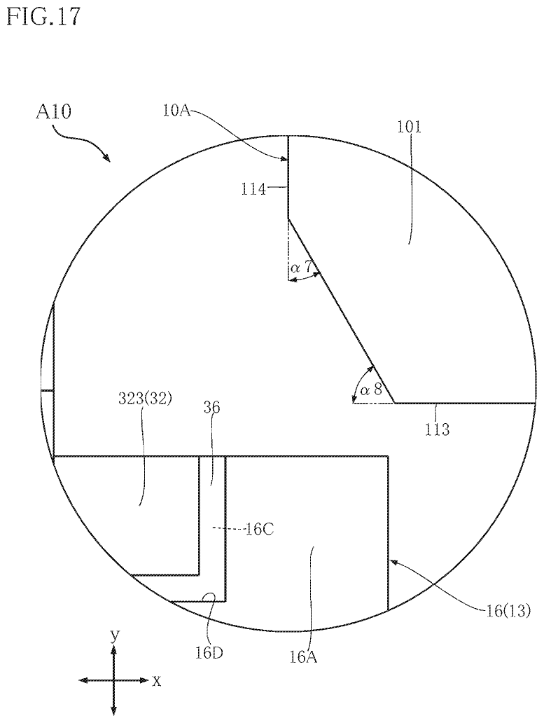

As shown in FIGS. 3 and 4, each of the first die pad 10A and the second die pad 10B has a fourth corner end surface 124. The fourth corner end surface 124 is located between the third end surface 113 and the fourth end surface 114 and at a corner of one of the first die pad 10A and the second die pad 10B. The fourth corner end surface 124 is a flat surface that is covered with the sealing resin 50, and that is inclined relative to the third end surface 113 and the fourth end surface 114. As shown in FIG. 17, the fourth corner end surface 124 has a seventh inclination angle α7 relative to the fourth end surface 114 and an eighth inclination angle α8 relative to the third end surface 113. Either the seventh inclination angle α7 or the eighth inclination angle α8 is in the range of 60° to 85° (both inclusive).

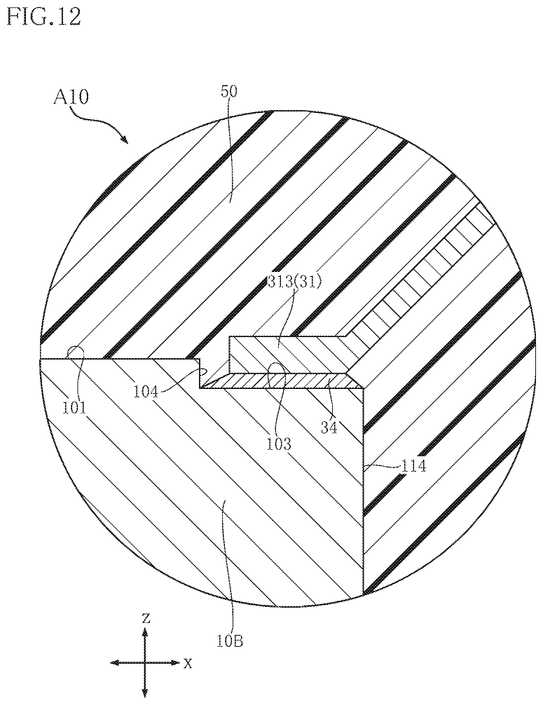

As shown in FIG. 12, the second die pad 10B has a first seating surface 103 and a first upright surface 104. The first seating surface 103 faces the same side as the obverse surface 101 in the thickness direction z, and is located between the obverse surface 101 and the reverse surface 102 in the thickness direction z. The first seating surface 103 is connected to the fourth end surface 114. The first upright surface 104 faces in a direction perpendicular to the thickness direction z and is connected to the first seating surface 103 and the obverse surface 101. The first seating surface 103 and the first upright surface 104 form a step in the second die pad 10B.

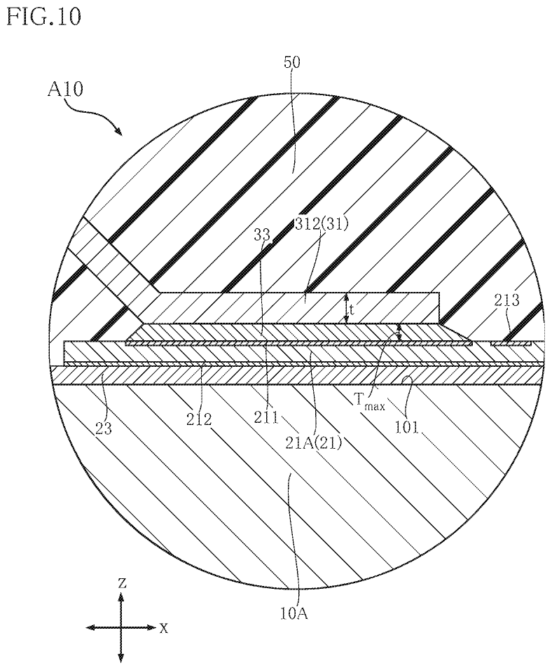

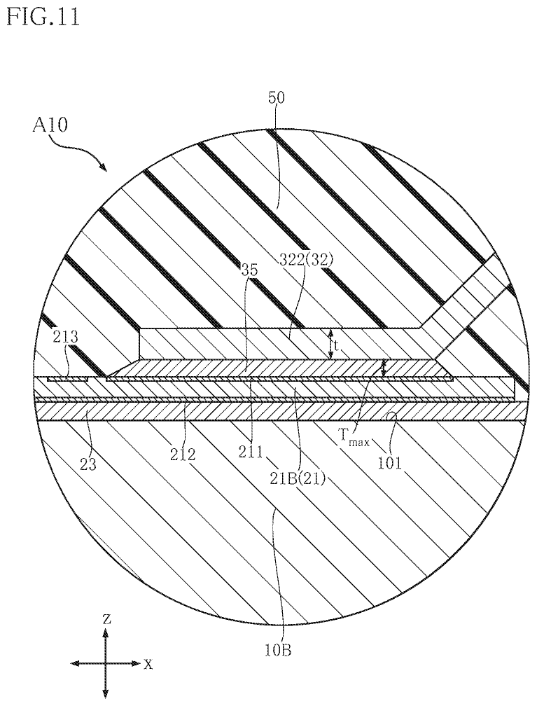

As shown in FIGS. 3 and 8, the semiconductor element 21 is mounted on at least one of the first die pad 10A and the second die pad 10B. In the semiconductor device A10, the semiconductor element 21 includes a first element 21A and a second element 21B. The first element 21A is mounted on the obverse surface 101 of the first die pad 10A. The second element 21B is mounted on the obverse surface 101 of the second die pad 10B. For example, the semiconductor element 21 is a metal-oxide-semiconductor field-effect transistor (MOSFET). Alternatively, the semiconductor element 21 may be a switching element such as an insulated gate bipolar transistor (IGBT) or a diode. In the description of the semiconductor device A10, the semiconductor element 21 is an n-channel type MOSFET with a vertical structure. The semiconductor element 21 includes a compound semiconductor substrate. The compound semiconductor substrate contains silicon carbide (SiC) in its composition. As shown in FIGS. 10 and 11, the semiconductor element 21 includes a first electrode 211, a second electrode 212, and a gate electrode 213.

As shown in FIGS. 10 and 11, the first electrode 211 is positioned opposite from the second electrode 212 in the thickness direction z. The current flowing through the first electrode 211 corresponds to the electric power that has been converted by the semiconductor element 21. In other words, the first electrode 211 corresponds to the source electrode of the semiconductor element 21. The first electrode 211 includes a plurality of metal plating layers. Specifically, the first electrode 211 includes a nickel (Ni) plating layer and a gold (Au) plating layer stacked on the nickel plating layer. Alternatively, the first electrode 211 may include a nickel plating layer, a palladium (Pd) plating layer stacked on the nickel plating layer, and a gold plating layer stacked on the palladium plating layer.

As shown in FIGS. 10 and 11, the second electrode 212 is provided to face either the obverse surface 101 of the first die pad 10A or the obverse surface 101 of the second die pad 10B. The current flowing through the second electrode 212 corresponds to the electric power that has yet to be converted by the semiconductor element 21. In other words, the first electrode 221 corresponds to the drain electrode of the semiconductor element 21.

As shown in FIGS. 10 and 11, the gate electrode 213 is positioned on the same side as the first electrode 211 in the thickness direction z. A gate voltage for driving the semiconductor element 21 is applied to the gate electrode 213. As viewed in the thickness direction z, the area of the gate electrode 213 is smaller than the area of the first electrode 211.

As shown in FIGS. 8, 10 and 11, a die bonding layer 23 is provided between the second electrode 212 of the semiconductor element 21 (i.e., the first element 21A and the second element 21B) and each of the obverse surface 101 of the first die pad 10A and the obverse surface 101 of the second die pad 10B. The die bonding layer 23 is electrically conductive. The die bonding layer 23 is solder, for example. Alternatively, the die bonding layer 23 may be a sintered metal. The die bonding layer 23 bonds the obverse surface 101 of the first die pad 10A and the second electrode 212 of the first element 21A. As a result, the second electrode 212 of the first element 21A is electrically connected to the first die pad 10A. The die bonding layer 23 further bonds the obverse surface 101 of the second die pad 10B and the second electrode 212 of the second element 21B. As a result, the second electrode 212 of the second element 21B is electrically connected to the second die pad 10B.

As shown in FIG. 3, the terminal leads 13 are positioned relative to the first die pad 10A and the second die pad 10B in a sense of the second direction y, which is opposite from another sense of the second direction y in which the second end surfaces 112 face. At least one of the terminal leads 13 is electrically connected to the semiconductor element 21. The terminal leads 13 are arranged in the first direction x. The terminal leads 13 include the first input terminal 14, the output terminal 15, the second input terminal 16, a first gate terminal 171, a second gate terminal 172, the first detection terminal 181, and the second detection terminal 182.

As shown in FIG. 3, the first input terminal 14 includes a portion extending in the second direction y, and is connected to the first die pad 10A. Accordingly, the first input terminal 14 is electrically connected to the second electrode 212 of the first element 21A via the first die pad 10A. The first input terminal 14 is a P terminal (positive electrode) to which the DC source voltage targeted for conversion is applied. The first input terminal 14 has a covered portion 14A and an exposed portion 14B. As shown in FIG. 7, the covered portion 14A is connected to the third end surface 113 of the first die pad 10A, and is covered with the sealing resin 50. As viewed in the first direction x, the covered portion 14A is bent. As shown in FIGS. 2 to 5, the exposed portion 14B is connected to the covered portion 14A, and is exposed from the third side surface 55 of the sealing resin 50. The exposed portion 14B extends away from the first die pad 10A in the second direction y. The surface of the exposed portion 14B is plated with tin, for example.

As shown in FIG. 3, the output terminal 15 includes a portion extending in the second direction y, and is connected to the second die pad 10B. Accordingly, the output terminal 15 is electrically connected to the second electrode 212 of the second element 21B via the second die pad 10B. The AC power resulting from the conversion by the semiconductor element 21 is outputted from the output terminal 15. The output terminal 15 has a covered portion 15A and an exposed portion 15B. The covered portion 15A is connected to the third end surface 113 of the second die pad 10B, and is covered with the sealing resin 50. As viewed in the first direction x, the covered portion 15A is bent in the same manner as the covered portion 14A of the first input terminal 14. As shown in FIGS. 2 to 5, the exposed portion 15B is connected to the covered portion 15A, and is exposed from the third side surface 55 of the sealing resin 50. The exposed portion 15B extends away from the second die pad 10B in the second direction y. The surface of the exposed portion 14B is plated with tin, for example.

As shown in FIG. 3, the second input terminal 16 is positioned away from the first die pad 10A and the second die pad 10B in the second direction y and between the first input terminal 14 and the output terminal 15 in the first direction x. The second input terminal 16 extends in the second direction y. The second input terminal 16 is electrically connected to the first electrode 211 of the second element 21B. The second input terminal 16 is an N terminal (negative electrode) to which the DC source voltage targeted for conversion is applied. The second input terminal 16 has a covered portion 16A and an exposed portion 16B. As shown in FIG. 9, the covered portion 16A is covered with the sealing resin 50. As shown in FIGS. 2 to 5, the exposed portion 16B is connected to the covered portion 16A, and is exposed from the third side surface 55 of the sealing resin 50. The exposed portion 16B extends away from the first die pad 10A and the second die pad 10B in the second direction y. The surface of the exposed portion 16B is plated with tin, for example.

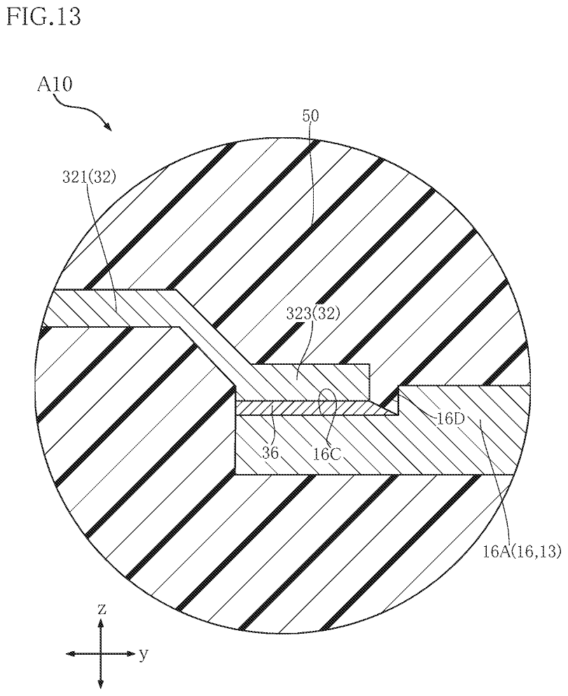

As shown in FIG. 13, the covered portion 16A of the second input terminal 16 has a second seating surface 16C and a second upright surface 16D. The second seating surface 16C faces the same side as the obverse surfaces 101 of the first die pad 10A and the second die pad 10B in the thickness direction z, and is positioned below the upper surface (i.e., the surface facing upward in FIG. 13) of the covered portion 16A in FIG. 13. The second upright surface 16D faces in a direction perpendicular to the thickness direction z, and is connected to the second seating surface 16C and the upper surface of the covered portion 16A. The second seating surface 16C and the second upright surface 16D form a step in the covered portion 16A of the second input terminal 16.

As shown in FIG. 3, the first gate terminal 171 is positioned away from the first die pad 10A in the second direction y, and is positioned in one sense of the first direction x. As shown in FIG. 3, the second gate terminal 172 is positioned away from the second die pad 10B in the second direction y, and is positioned in the other sense of the first direction x. The first gate terminal 171 is electrically connected to the gate electrode 213 of the first element 21A. A gate voltage for driving the first element 21A is applied to the first gate terminal 171. The second gate terminal 172 is electrically connected to the gate electrode 213 of the second element 21B. A gate voltage for driving the second element 21B is applied to the second gate terminal 172.

As shown in FIG. 3, the first gate terminal 171 has a covered portion 171A and an exposed portion 171B. The covered portion 171A is covered with the sealing resin 50. As shown in FIGS. 2 to 5, the exposed portion 171B is connected to the covered portion 171A, and is exposed from the third side surface 55 of the sealing resin 50. The exposed portion 171B extends away from the first die pad 10A in the second direction y. The surface of the exposed portion 171B is plated with tin, for example.

As shown in FIG. 3, the second gate terminal 172 has a covered portion 172A and an exposed portion 172B. The covered portion 172A is covered with the sealing resin 50. As shown in FIGS. 2 to 5, the exposed portion 172B is connected to the covered portion 172A, and is exposed from the sealing resin 50. The exposed portion 172B extends away from the second die pad 10B in the second direction y. The surface of the exposed portion 172B is plated with tin, for example.

As shown in FIG. 3, the first detection terminal 181 is positioned away from the first die pad 10A in the second direction y, and is positioned between the first input terminal 14 and the first gate terminal 171 in the first direction x. As shown in FIG. 3, the second detection terminal 182 is positioned away from the second die pad 10B in the second direction y, and is positioned between the output terminal 15 and the second gate terminal 172 in the first direction x. The first detection terminal 181 is electrically connected to the first electrode 211 of the first element 21A. A voltage corresponding to the current flowing through the first electrode 211 of the first element 21A is applied to the first detection terminal 181. The second detection terminal 182 is electrically connected to the first electrode 211 of the second element 21B. A voltage corresponding to the current flowing through the first electrode 211 of the second element 21B is applied to the second detection terminal 182.

As shown in FIG. 3, the first detection terminal 181 has a covered portion 181A and an exposed portion 181B. The covered portion 181A is covered with the sealing resin 50. As shown in FIGS. 2 to 5, the exposed portion 181B is connected to the covered portion 181A, and is exposed from the third side surface 55 of the sealing resin 50. The exposed portion 181B extends away from the first die pad 10A in the second direction y. The surface of the exposed portion 181B is plated with tin, for example.

As shown in FIG. 3, the second detection terminal 182 has a covered portion 182A and an exposed portion 182B. The covered portion 182A is covered with the sealing resin 50. As shown in FIGS. 2 to 5, the exposed portion 182B is connected to the covered portion 182A, and is exposed from the third side surface 55 of the sealing resin 50. The exposed portion 182B extends away from the second die pad 10B in the second direction y. The surface of the exposed portion 182B is plated with tin, for example.

As shown in FIG. 5, in the semiconductor device A10, the exposed portion 14B of the first input terminal 14, the exposed portion 15B of the output terminal 15, and the exposed portion 16B of the second input terminal 16 have the same height h. These exposed portions also have the same thickness. Thus, as viewed in the first direction x, at least a portion (exposed portion 16B) of the second input terminal 16 overlaps with the first input terminal 14 and the output terminal 15 (see FIG. 6).

As shown in FIG. 3, the first conductive member 31 is bonded to the first electrode 211 of the first element 21A and the second die pad 10B. As a result, the first electrode 211 of the first element 21A is electrically connected to the second die pad 10B and the second electrode 212 of the second element 21B. The first conductive member 31 contains copper in its composition. In the semiconductor device A10, the first conductive member 31 is a metal clip. The first conductive member 31 has a body 311, a pair of first bonding portions 312, and a second bonding portion 313.

As shown in FIG. 3, the body 311 forms a main part of the first conductive member 31. The body 311 extends in the first direction x. As shown in FIG. 8, the body 311 extends across the first die pad 10A and the second die pad 10B.

As shown in FIGS. 3 and 10, the pair of first bonding portions 312 are bonded to the first electrode 211 of the first element 21A. As shown in FIGS. 3 and 7, the pair of first bonding portions 312 are spaced apart from each other in the second direction y. The pair of first bonding portions 312 are connected to the body 311.

As shown in FIGS. 3 and 12, the second bonding portion 313 is bonded to the first seating surface 103 of the second die pad 10B. The second bonding portion 313 extends in the second direction y. At least a part of the second bonding portion 313 is housed in the area defined by the first seating surface 103 and the first upright surface 104 of the second die pad 10B. The second bonding portion 313 is connected to the body 311. The second bonding portion 313 is positioned opposite from the pair of first bonding portions 312 with the body 311 therebetween.

As shown in FIGS. 8 and 10, the semiconductor device A10 further includes a first bonding layer 33. The first bonding layer 33 is provided between the first electrode 211 of the first element 21A and the pair of first bonding portions 312. The first bonding layer 33 bonds the first electrode 211 of the first element 21A and the pair of first bonding portions 312. The first bonding layer 33 is electrically conductive. The first bonding layer 33 is solder, for example. Alternatively, the first bonding layer 33 may be a sintered metal.

The thickness t of each of the pair of first bonding portions 312 is at least 0.1 mm, and is not greater than twice the maximum thickness Tₘₐₓ of the first bonding layer 33. The maximum thickness Tₘₐₓ of the first bonding layer 33 is greater than the thickness of the first element 21A.

As shown in FIGS. 8 and 12, the semiconductor device A10 further includes a second bonding layer 34. The second bonding layer 34 is provided between the first seating surface 103 of the second die pad 10B and the second bonding portion 313. The second bonding layer 34 bonds the second die pad 10B and the second bonding portion 313. The second bonding layer 34 is electrically conductive. The second bonding layer 34 is solder, for example. Alternatively, the second bonding layer 34 may be a sintered metal.

As shown in FIG. 3, the second conductive member 32 is bonded to the first electrode 211 of the second element 21B and the covered portion 16A of the second input terminal 16. As a result, the first electrode 211 of the second element 21B is electrically connected to the second input terminal 16. The second conductive member 32 contains copper in its composition. In the semiconductor device A10, the second conductive member 32 is a metal clip. The second conductive member 32 has a body 321, a pair of third bonding portions 322, and a fourth bonding portion 323.

As shown in FIG. 3, the body 321 forms a main part of the second conductive member 32. As viewed in the thickness direction z, the body 321 is bent into a hook shape. As viewed in the thickness direction z, the body 321 overlaps with the obverse surface 101 of the second die pad 10B.

As shown in FIGS. 3 and 11, the pair of third bonding portions 322 are bonded to the first electrode 211 of the second element 21B. As shown in FIGS. 3 and 9, the pair of third bonding portions 322 are spaced apart from each other in the second direction y. The pair of third bonding portions 322 are connected to the body 321.

As shown in FIGS. 3 and 13, the fourth bonding portion 323 is bonded to the second seating surface 16C of the second input terminal 16. The fourth bonding portion 323 extends in the first direction x. At least a part of the fourth bonding portion 323 is housed in the area defined by the second seating surface 16C and the second upright surface 16D of the second input terminal 16. The fourth bonding portion 323 is connected to the body 321. The fourth bonding portion 323 is positioned opposite from the pair of third bonding portions 322 with the body 321 therebetween.

As shown in FIGS. 8 and 11, the semiconductor device A10 further includes a third bonding layer 35. The third bonding layer 35 is provided between the first electrode 211 of the second element 21B and the pair of third bonding portions 322. The third bonding layer 35 bonds the first electrode 211 of the second element 21B and the pair of third bonding portions 322. The third bonding layer 35 is electrically conductive. The third bonding layer 35 is solder, for example. Alternatively, the third bonding layer 35 may be a sintered metal.

The thickness t of each of the pair of third bonding portions 322 is at least 0.1 mm, and is not greater than twice the maximum thickness Tₘₐₓ of the third bonding layer 35. The maximum thickness Tₘₐₓ of the third bonding layer 35 is greater than the thickness of the second element 21B.

As shown in FIGS. 8 and 13, the semiconductor device A10 further includes a fourth bonding layer 36. The fourth bonding layer 36 is provided between the second seating surface 16C of the second input terminal 16 and the fourth bonding portion 323. The fourth bonding layer 36 bonds the covered portion 16A of the second input terminal 16 and the fourth bonding portion 323. The fourth bonding layer 36 is electrically conductive. The fourth bonding layer 36 is solder, for example. Alternatively, the fourth bonding layer 36 may be a sintered metal.

As shown in FIG. 3, one of the pair of gate wires 41 is bonded to the gate electrode 213 of the first element 21A and the covered portion 171A of the first gate terminal 171, and the other is bonded to the gate electrode 213 of the second element 21B and the covered portion 172A of the second gate terminal 172. As a result, the first gate terminal 171 is electrically connected to the gate electrode 213 of the first element 21A. The second gate terminal 172 is electrically connected to the gate electrode 213 of the second element 21B. The pair of gate wires 41 contain gold in their compositions. Alternatively, the pair of gate wires 41 may contain copper or aluminum (Al).

As shown in FIG. 3, one of the pair of detection wires 42 is bonded to the first electrode 211 of the first element 21A and the covered portion 181A of the first detection terminal 181, and the other is bonded to the first electrode 211 of the second element 21B and the covered portion 182A of the second detection terminal 182. As a result, the first detection terminal 181 is electrically connected to the first electrode 211 of the first element 21A. The second detection terminal 182 is electrically connected to the first electrode 211 of the second element 21B. The pair of detection wires 42 contain gold in their compositions. Alternatively, the pair of detection wires 42 may contain copper or aluminum (Al).

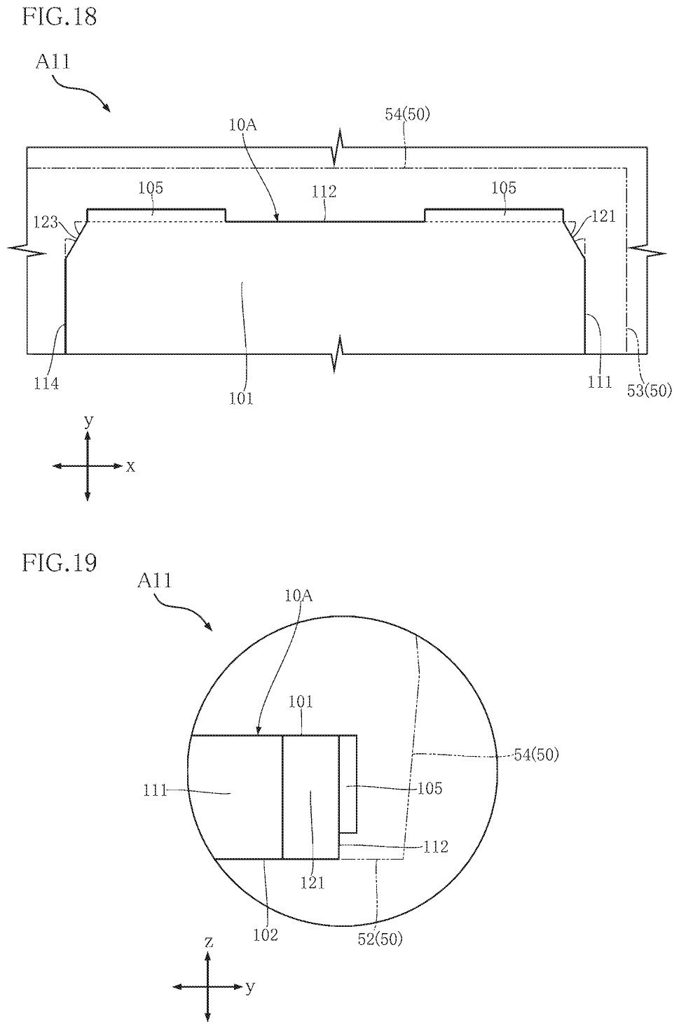

Next, a semiconductor device A11, which is a variation of the semiconductor device A10, will be described with reference to FIGS. 18 and 19. In FIGS. 18 and 19, the sealing resin 50 is shown transparent for convenience of understanding and indicated by an imaginary line.

As shown in FIG. 18, the first die pad 10A of the semiconductor device A11 has an eave portion 105. The eave portion 105 protrudes from the second end surface 112 in the second direction y. The eave portion 105 includes a pair of areas spaced apart from each other in the first direction x. Furthermore, the eave portion 105 includes the obverse surface 101. As shown FIG. 19, the eave portion 105 is positioned away from the reverse surface 102 in the thickness direction z. The eave portion 105 is provided so as to prevent the first die pad 10A from falling off the bottom surface 52 of the sealing resin 50. The eave portion 105 is not limited to the above configuration, and may be configured to protrude from at least one of the first end surface 111, the third end surface 113, and the fourth end surface 114 in a direction perpendicular to the thickness direction z. Furthermore, a configuration similar to the eave portion 105 may be provided for the second die pad 10B.

The following describes advantages of the semiconductor device A10.

The semiconductor device A10 includes the first die pad 10A and the second die pad 10B that are spaced apart from each other in the first direction x, and the sealing resin 50 that covers at least a portion of each of the first die pad 10A and the second die pad 10B. The first die pad 10A has the first end surface 111, the second end surface 112, and the first corner end surface 121. The first corner end surface 121 is a flat surface that is covered with the sealing resin 50, and that is inclined relative to the first end surface 111 and the second end surface 112. Either the first inclination angle α1 of the first corner end surface 121 relative to the first end surface 111, which is shown in FIG. 14, or the second inclination angle α2 of the first corner end surface 121 relative to the second end surface 112, which is also shown in FIG. 14, is in the range of 60° to 85° (both inclusive). With this configuration, the thermal strain of the sealing resin 50 is reduced at the interface with the first corner end surface 121 as compared to the case where each of the first inclination angle α1 and the second inclination angle α2 is 45°. As a result, the thermal stress is reduced at the interface. This makes it possible to reduce the thermal stress of the sealing resin 50 near the boundary between the first side surface 53 and the second side surface 54. Accordingly, the semiconductor device A10 can alleviate the thermal stress concentration at the sealing resin 50.

The maximum length (longest normal Nₘₐₓ shown in FIG. 14) of the normal of the first corner end surface 121 that extends from the first corner end surface 121 to the first side surface 53 of the sealing resin 50 serves as a parameter for the magnitude of the thermal strain of the sealing resin 50 at the interface with the first corner end surface 121. In FIG. 14, when the longest normal Nₘₐₓ is 1.0 to 1.5 times the line of intersection C between the first corner end surface 121 and the virtual plane having the first direction x and the second direction y as in-plane directions, the thermal strain of the sealing resin 50 at the interface with the first corner end surface 121 is relatively small.

The first die pad 10A further has the third end surface 113 and the second corner end surface 122. The second corner end surface 122 is a flat surface that is covered with the sealing resin 50, and that is inclined relative to the first end surface 111 and the third end surface 113. Either the third inclination angle α3 of the second corner end surface 122 relative to the first end surface 111, which is shown in FIG. 15, and the fourth inclination angle α4 of the second corner end surface 122 relative to the third end surface 113, which is also shown in FIG. 15, is in the range of 60° to 85° (both inclusive). In this way, as with the advantage of the first corner end surface 121 described above, the thermal strain of the sealing resin 50 at the interface with the second corner end surface 122 is reduced, thus leading to the reduction of thermal stress at the interface. This makes it possible to reduce the thermal stress of the sealing resin 50 near the boundary between the first side surface 53 and the third side surface 55. Accordingly, the thermal stress concentration at the sealing resin 50 can be more effectively alleviated.

The first die pad 10A further has the third corner end surface 123 and the fourth corner end surface 124. The third corner end surface 123 is a flat surface that is covered with the sealing resin 50, and that is inclined relative to the second end surface 112 and the fourth end surface 114. The fourth corner end surface 124 is a flat surface that is covered with the sealing resin 50, and that is inclined relative to the third end surface 113 and the fourth end surface 114. In this way, as with the advantage of the first corner end surface 121 described above, the thermal strain of the sealing resin 50 at the interface with the third corner end surface 123 and at the interface with the fourth corner end surface 124 is reduced, thus leading to the reduction of thermal stress at the interface. This makes it possible to reduce the thermal stress of the sealing resin 50 in the area between the first die pad 10A and the second die pad 10B.

The distance P2 between the third end surface 113 and the third side surface 55 of the sealing resin 50 is longer than the distance P1 between the second end surface 112 and the second side surface 54 of the sealing resin 50. In this way, a portion of each of the terminal leads 13 can be enclosed by the sealing resin 50 with a margin.

The sealing resin 50 has the plurality of recesses 56 recessed from the third side surface 55 in the second direction y. This configuration ensures a longer creepage distance of the sealing resin 50 between any two of the terminal leads 13 (except the first gate terminal 171, the first detection terminal 181, the second gate terminal 172, and the second detection terminal 182). This makes it possible to improve the dielectric strength of the semiconductor device A10.

The sealing resin 50 has the groove 57 that is recessed from the bottom surface 52, and that divides the reverse surface 102 of the first die pad 10A and the reverse surface 102 of the second die pad 10B as viewed in the thickness direction z. This configuration ensures a longer creepage distance of the sealing resin 50 between the first die pad 10A and the second die pad 10B. This further improves the dielectric strength of the semiconductor device A10. Furthermore, the thermal strain of the sealing resin 50 in the first direction x can be dispersed. This alleviates the concentration of the thermal strain at the pair of first side surfaces 53 of the sealing resin 50.

At least one of the terminal leads 13 is connected to the third end surface 113 of the first die pad 10A. In this way, the first die pad 10A can be utilized as a conductive member while suppressing an increase in the dimensions of the semiconductor device A10.

The reverse surfaces 102 of the first die pad 10A and the second die pad 10B are exposed from the sealing resin 50. This improves the heat dissipation of the semiconductor device A10.

Each of the first conductive member 31 and the second conductive member 32 contains copper in its composition. This reduces the electric resistance of the first conductive member 31 and the second conductive member 32 as compared to a wire containing aluminum in its composition. This is suitable for passing a larger current through the semiconductor element 21.

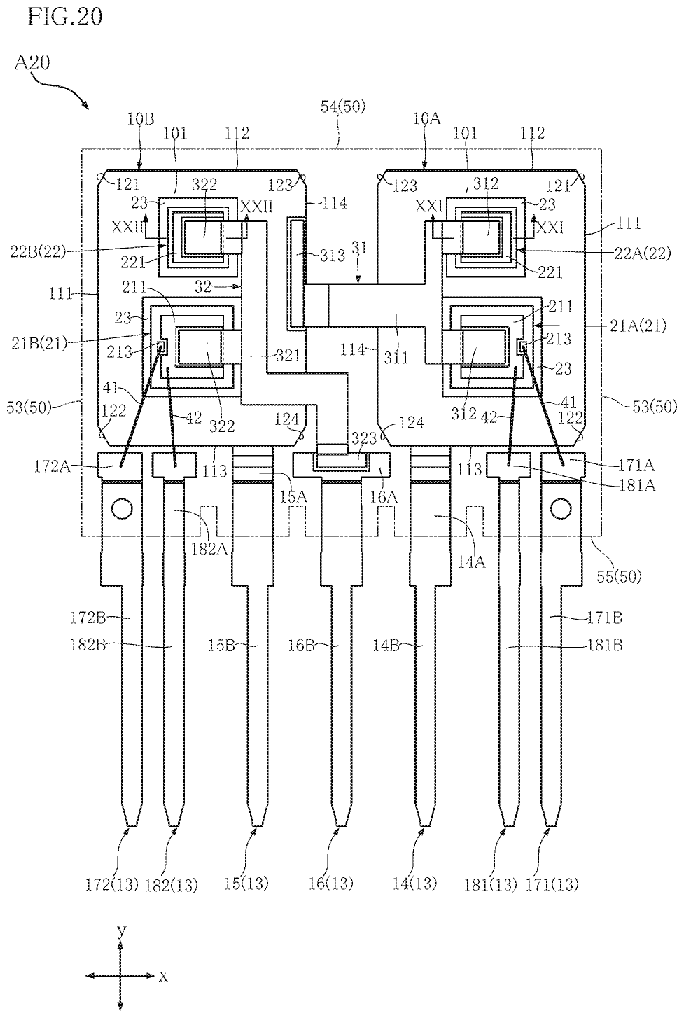

The following describes a semiconductor device A20 according to a second embodiment of the present disclosure, with reference to FIGS. 20 to 22. In these figures, elements that are the same as or similar to those of the semiconductor device A10 are denoted by the same reference signs and the descriptions thereof are omitted. In FIG. 20, the sealing resin 50 is shown transparent for convenience of understanding and indicated by an imaginary line.

The semiconductor device A20 is different from the semiconductor device A10 in further including a protective element 22 and in the configurations of the first conductive member 31 and the second conductive member 32.

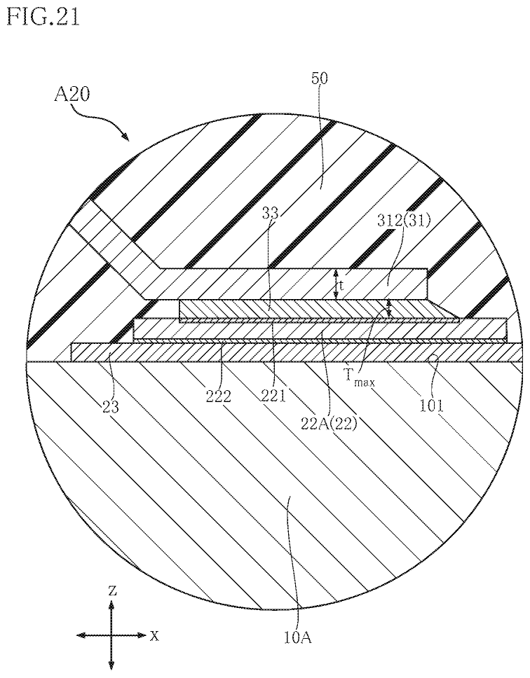

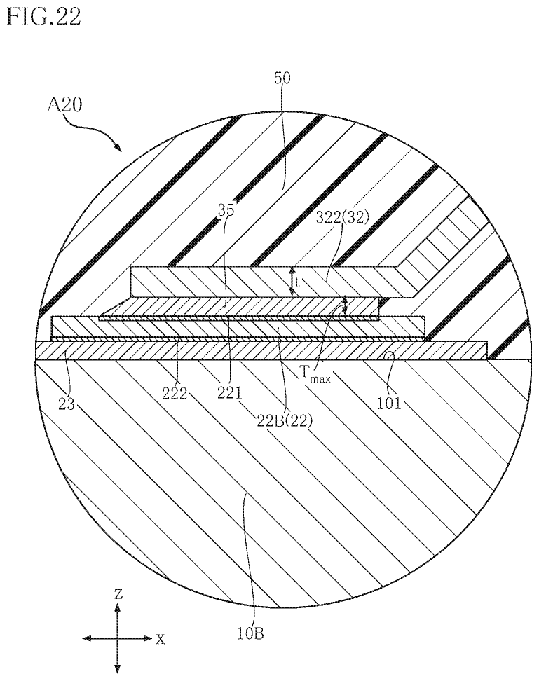

As shown in FIG. 20, the protective element 22 includes a first diode 22A and a second diode 22B. The first diode 22A is mounted on the obverse surface 101 of the first die pad 10A. The second diode 22B is mounted on the obverse surface 101 of the second die pad 10B. The protective element 22 is a Schottky barrier diode, for example. The first diode 22A is connected in parallel to the first element 21A. The second diode 22B is connected in parallel to the second element 21B. The protective element 22 is a so-called freewheeling diode that allows current to flow through the protective element 22 instead of the semiconductor element 21 when a reverse bias is applied to the semiconductor element 21. As shown in FIGS. 21 and 22, the protective element 22 includes an upper electrode 221 and a lower electrode 222.

As shown in FIGS. 21 and 22, the upper electrode 221 is provided in the sense of the thickness direction z in which the obverse surfaces 101 of the first die pad 10A and the second die pad 10B face. The upper electrode 221 corresponds to an anode electrode.

As shown in FIGS. 21 and 22, the lower electrode 222 is provided opposite from the upper electrode 221 in the thickness direction z. The lower electrode 222 corresponds to a cathode electrode. As shown in FIG. 21, the lower electrode 222 of the first diode 22A is bonded to the obverse surface 101 of the first die pad 10A via the die bonding layer 23. As a result, the lower electrode 222 of the first diode 22A is electrically connected to the second electrode 212 of the first element 21A via the first die pad 10A. As shown in FIG. 22, the lower electrode 222 of the second diode 22B is bonded to the obverse surface 101 of the second die pad 10B via the die bonding layer 23. As a result, the lower electrode 222 of the second diode 22B is electrically connected to the second electrode 212 of the second element 21B via the second die pad 10B.

As shown in FIGS. 20 and 21, one of the pair of first bonding portions 312 of the first conductive member 31 is bonded to the upper electrode 221 of the first diode 22A via the first bonding layer 33. As a result, the upper electrode 221 of the first diode 22A is electrically connected to the first electrode 211 of the first element 21A via the first conductive member 31.

As shown in FIGS. 20 and 22, one of the pair of third bonding portions 322 of the second conductive member 32 is bonded to the upper electrode 221 of the second diode 22B via the third bonding layer 35. As a result, the upper electrode 221 of the second diode 22B is electrically connected to the first electrode 211 of the second element 21B via the second conductive member 32.

The following describes advantages of the semiconductor device A20.

The semiconductor device A20 includes the first die pad 10A and the second die pad 10B that are spaced apart from each other in the first direction x, and the sealing resin 50 that covers at least a portion of each of the first die pad 10A and the second die pad 10B. The first die pad 10A has the first end surface 111, the second end surface 112, and the first corner end surface 121. The first corner end surface 121 is a flat surface that is covered with the sealing resin 50, and that is inclined relative to the first end surface 111 and the second end surface 112. Either the first inclination angle α1 of the first corner end surface 121 relative to the first end surface 111, which is shown in FIG. 14, or the second inclination angle α2 of the first corner end surface 121 relative to the second end surface 112, which is also shown in FIG. 14, is in the range of 60° to 85° (both inclusive). Accordingly, the semiconductor device A20 can also alleviate the thermal stress concentration at the sealing resin 50. Furthermore, the semiconductor device A20 has configurations similar to the semiconductor device A10, whereby the semiconductor device A20 also has advantages owing to the configurations.

The semiconductor device A20 further includes the protective element 22. As such, even if a larger current flows through the semiconductor device A20, the semiconductor element 21 is appropriately protected from a reverse bias.

The present disclosure is not limited to the above embodiments. Various design changes can be made to the specific configurations of the elements in the present disclosure.

The present disclosure includes the embodiments described in the following clauses.

Clause 1.

A semiconductor device comprising:

a first die pad and a second die pad spaced apart from each other in a first direction perpendicular to a thickness direction;

a semiconductor element mounted on at least one of the first die pad and the second die pad; and

a sealing resin covering the semiconductor element and at least a portion of each of the first die pad and the second die pad,

wherein a dimension of the sealing resin in the first direction is longer than a dimension of the sealing resin in a second direction perpendicular to the thickness direction and the first direction,

the first die pad has a first end surface facing in the first direction, a second end surface facing in the second direction, and a first corner end surface located between the first end surface and the second end surface and at a corner of the first die pad,

the first corner end surface is a flat surface that is covered with the sealing resin, and that is inclined relative to the first end surface and the second end surface, and

one of a first inclination angle of the first corner end surface relative to the first end surface and a second inclination angle of the first corner end surface relative to the second end surface is in the range of 60° to 85° both inclusive.

Clause 2.

The semiconductor device according to clause 1, wherein the first end surface and the second end surface are covered with the sealing resin.

Clause 3.

The semiconductor device according to clause 2, wherein the sealing resin has a first side surface facing in the first direction, and

the first end surface is located closest to the first side surface.

Clause 4.

The semiconductor device according to clause 3, wherein a maximum length of a normal of the first corner end surface that extends from the first corner end surface to the first side surface is 1.0 to 1.5 times greater than a length of a line of intersection between the first corner end surface and a virtual plane having the first direction and the second direction as in-plane directions.

Clause 5.

The semiconductor device according to clause 3 or 4, wherein each of the first die pad and the second die pad has a reverse surface facing away from where the semiconductor element is located in the thickness direction, and

the reverse surface is exposed from the sealing resin.

Clause 6.

The semiconductor device according to clause 5, further comprising a plurality of terminal leads positioned relative to the first die pad and the second die pad in a sense of the second direction, which is opposite from another sense of the second direction in which the second end surface faces,

wherein at least one of the terminal leads is electrically connected to the semiconductor element, and

a portion of each of the terminal leads is covered with the sealing resin.

Clause 7.

The semiconductor device according to clause 6, wherein the plurality of terminal leads are arranged in the first direction.

Clause 8.

The semiconductor device according to clause 6 or 7, wherein the first die pad has a third end surface facing away from the second end surface in the second direction, and a second corner end surface located between the first end surface and the third end surface and at a corner of the first die pad,

the third end surface and the second corner end surface are covered with the sealing resin,

the second corner end surface is a flat surface inclined relative to the first end surface and the third end surface, and

one of a third inclination angle of the second corner end surface relative to the first end surface and a fourth inclination angle of the second corner end surface relative to the third end surface is in the range of 60° to 85° both inclusive.

Clause 9.

The semiconductor device according to clause 8, wherein the first die pad has a fourth end surface facing away from the first end surface in the first direction, and a third corner end surface located between the second end surface and the fourth end surface and at a corner of the first die pad,

the fourth end surface and the third corner end surface are covered with the sealing resin, and

the third corner end surface is a flat surface inclined relative to the second end surface and the fourth end surface.

Clause 10.

The semiconductor device according to clause 9, wherein the first die pad has a fourth corner end surface located between the third end surface and the fourth end surface and at a corner of the first die pad, and

the fourth corner end surface is a flat surface that is covered with the sealing resin, and that is inclined relative to the third end surface and the fourth end surface.

Clause 11.

The semiconductor device according to any of clauses 8 to 10, wherein the sealing resin has a second side surface and a third side surface facing away from each other in the second direction, and

the second end surface is located closest to the second side surface.

Clause 12.

The semiconductor device according to clause 11, wherein a distance between the third end surface and the third side surface is longer than a distance between the second end surface and the second side surface.

Clause 13.

The semiconductor device according to clause 12, wherein the plurality of terminal leads are exposed from the third side surface.

Clause 14.

The semiconductor device according to clause 13, wherein one of the plurality of terminal leads is connected to the third end surface of the first die pad.

Clause 15.

The semiconductor device according to any of clauses 12 to 14, wherein the semiconductor element includes a first element and a second element,

the first element is mounted on the first die pad, and

the second element is mounted on the second die pad.

Clause 16.

The semiconductor device according to clause 15, wherein the first element is electrically connected to the first die pad, and

the second element is electrically connected to the second die pad.

Clause 17.

The semiconductor device according to clause 16, further comprising:

a first conductive member bonded to the first element and the second die pad; and

a second conductive member bonded to the second die pad and one of the plurality of terminal leads,

wherein the first conductive member and the second conductive member are covered with the sealing resin.

### REFERENCE SIGNS

A10, A20: Semiconductor device 10A: First die pad
10B: Second die pad 101: Obverse surface
102: Reverse surface 103: First seating surface
104: First upright surface 105: Eave portion
111: First end surface 112: Second end surface
113: Third end surface 114: Fourth end surface
121: First corner end surface 122: Second corner end surface
123: Third corner end surface 124: Fourth corner end surface
13: Terminal lead 14: First input terminal
14A: Covered portion 14B: Exposed portion
15: Output terminal 15A: Covered portion
15B: Exposed portion 16: Second input terminal
16A: Covered portion 16B: Exposed portion
16C: Second seating surface 16D: Second upright surface
171: First gate terminal 171A: Covered portion
171B: Exposed portion 172: Second gate terminal
172A: Covered portion 172B: Exposed portion
181: First detection terminal 181A: Covered portion
181B: Exposed portion 182: Second detection terminal
182A: Covered portion 182B: Exposed portion
21: Semiconductor element 21A: First element
21B: Second element 211: First electrode
212: Second electrode 213: Gate electrode
22: Protective element 22A: First diode
22B: Second diode 221: Upper electrode
222: Lower electrode 23: Die bonding layer
31: First conductive member 311: Body
312: First bonding portion 313: Second bonding portion
32: Second conductive member 321: Body
322: Third bonding portion 323: Fourth bonding portion
33: First bonding layer 34: Second bonding layer
35: Third bonding layer 36: Fourth bonding layer
41: Gate wire 42: Detection wire
50: Sealing resin 51: Top surface
52: Bottom surface 53: First side surface
54: Second side surface 55: Third side surface
56: Recess 57: Groove
L1, L2: Dimension α1-α8: First inclination angle-Eighth inclination angle
P1, P2: Distance z: Thickness direction
x: First direction y: Second direction

1. A semiconductor device comprising:
a first die pad and a second die pad spaced apart from each other in a first direction perpendicular to a thickness direction;
a semiconductor element mounted on at least one of the first die pad and the second die pad; and
a sealing resin covering the semiconductor element and at least a portion of each of the first die pad and the second die pad,
wherein a dimension of the sealing resin in the first direction is longer than a dimension of the sealing resin in a second direction perpendicular to the thickness direction and the first direction,
the first die pad has a first end surface facing in the first direction, a second end surface facing in the second direction, and a first corner end surface located between the first end surface and the second end surface and at a corner of the first die pad,
the first corner end surface is a flat surface that is covered with the sealing resin, and that is inclined relative to the first end surface and the second end surface, and
one of a first inclination angle of the first corner end surface relative to the first end surface and a second inclination angle of the first corner end surface relative to the second end surface is in the range of 60° to 85° both inclusive.

2. The semiconductor device according to claim 1, wherein the first end surface and the second end surface are covered with the sealing resin.

3. The semiconductor device according to claim 2, wherein the sealing resin has a first side surface facing in the first direction, and
the first end surface is located closest to the first side surface.

4. The semiconductor device according to claim 3, wherein a maximum length of a normal of the first corner end surface that extends from the first corner end surface to the first side surface is 1.0 to 1.5 times greater than a length of a line of intersection between the first corner end surface and a virtual plane having the first direction and the second direction as in-plane directions.

5. The semiconductor device according to claim 3, wherein each of the first die pad and the second die pad has a reverse surface facing away from where the semiconductor element is located in the thickness direction, and
the reverse surface is exposed from the sealing resin.

6. The semiconductor device according to claim 5, further comprising a plurality of terminal leads positioned relative to the first die pad and the second die pad in a sense of the second direction, which is opposite from another sense of the second direction in which the second end surface faces,
wherein at least one of the terminal leads is electrically connected to the semiconductor element, and
a portion of each of the terminal leads is covered with the sealing resin.

7. The semiconductor device according to claim 6, wherein the plurality of terminal leads are arranged in the first direction.

8. The semiconductor device according to claim 6, wherein the first die pad has a third end surface facing away from the second end surface in the second direction, and a second corner end surface located between the first end surface and the third end surface and at a corner of the first die pad,
the third end surface and the second corner end surface are covered with the sealing resin,
the second corner end surface is a flat surface inclined relative to the first end surface and the third end surface, and
one of a third inclination angle of the second corner end surface relative to the first end surface and a fourth inclination angle of the second corner end surface relative to the third end surface is in the range of 60° to 85° both inclusive.

9. The semiconductor device according to claim 8, wherein the first die pad has a fourth end surface facing away from the first end surface in the first direction, and a third corner end surface located between the second end surface and the fourth end surface and at a corner of the first die pad,
the fourth end surface and the third corner end surface are covered with the sealing resin, and
the third corner end surface is a flat surface inclined relative to the second end surface and the fourth end surface.

10. The semiconductor device according to claim 9, wherein the first die pad has a fourth corner end surface located between the third end surface and the fourth end surface and at a corner of the first die pad, and
the fourth corner end surface is a flat surface that is covered with the sealing resin, and that is inclined relative to the third end surface and the fourth end surface.

11. The semiconductor device according to claim 8, wherein the sealing resin has a second side surface and a third side surface facing away from each other in the second direction, and
the second end surface is located closest to the second side surface.

12. The semiconductor device according to claim 11, wherein a distance between the third end surface and the third side surface is longer than a distance between the second end surface and the second side surface.

13. The semiconductor device according to claim 12, wherein the plurality of terminal leads are exposed from the third side surface.

14. The semiconductor device according to claim 13, wherein one of the plurality of terminal leads is connected to the third end surface of the first die pad.

15. The semiconductor device according to claim 12, wherein the semiconductor element includes a first element and a second element,
the first element is mounted on the first die pad, and
the second element is mounted on the second die pad.

16. The semiconductor device according to claim 15, wherein the first element is electrically connected to the first die pad, and
the second element is electrically connected to the second die pad.

17. The semiconductor device according to claim 16, further comprising:
a first conductive member bonded to the first element and the second die pad; and
a second conductive member bonded to the second die pad and one of the plurality of terminal leads,
wherein the first conductive member and the second conductive member are covered with the sealing resin.
